(19) United States
(12) Patent Application Publication
(10) Pub. No.: US 2008/0001145 A1
(43) Pub. Date: Jan. 3, 2008

(54) Handler for testing packaged chips

(75) Inventors: Sung Yong Chu, Junju-si (KR); Sung Mun Park, Cheonan-si (KR); Yong Jin Lim, Cheonan-si (KR)

Correspondence Address: KED & ASSOCIATES, LLP, P.O. Box 221200, Chantilly, VA, 20153-1200, US

(73) Assignee: Mirae Corporation

(21) Appl. No.: 11/802,041

(22) Filed: May 18, 2007

(30) Foreign Application Priority Data
May 24, 2006 (KR) 10-2006-0046516

(51) Int. Cl. H01L 23/58

(52) U.S. Cl. 257/48

(57) ABSTRACT

A handler for testing packaged semiconductor chips includes a tray-transferring apparatus. Transferring members in the form of rods with external screw threads hold sides of the tray. The rods are rotated together to move the trays in a longitudinal direction. A driving unit rotates the rods together. The tray-transferring apparatus does not apply vibration to the tray during transit. Thus, it is possible to minimize the likelihood that chips contained in the tray are ejected due to vibration generated during transfer of the tray.

### BACKGROUND

1. Field

The application discloses a handler for testing semiconductor chips, and more particularly, a handler equipped with a tray-transferring apparatus capable of transferring a tray containing the semiconductor chips in a smooth, speedy manner.

2. Background

After semiconductor chips have been formed and packaged, they are usually subjected to a series of environmental, electrical, and reliability tests. These tests vary in type and specifications, depending on the customer and use of the semiconductor chips. The tests may be performed on all of the chips in a lot, or on selected samples.

Environmental tests, such as temperature cycling, are performed to weed out leaking and defective packages. During temperature cycling testing, the semiconductor chips are loaded into a chamber and cycled between two temperature extremes. The number of cycles may reach several hundred. The high and low temperatures vary with the device. During the temperature cycling, any weakness in the seal, die attachment, or bonding will be aggravated and detected, in later electrical tests.

A handler for performing these tests is equipped with a chamber into which the semiconductor chips are loaded for temperature cycling. The chamber is typically equipped with an electric heater, and a liquefied nitrogen injecting system for cooling. These systems allow the semiconductor chips to be subjected to the temperature extremes, high and low.

The packaged chips are typically mounted on test trays. The test trays are then placed within the chamber during the temperature cycling. Usually, multiple trays are in the temperature cycling chamber at any given time. Test trays are inserted into one side of the chamber and are removed from the opposite side of the chamber. Temperature cycling occurs continuously as the test trays move from the input side to the output side.

In related art handlers, two or more holding rods and transferring rods act as a tray transferring apparatus to move the trays from the input side of the chamber to the output side of the chamber. The holding rods and transferring rods support sides of the trays and physically move the trays within the chamber. Teeth are provided at regular intervals along the holding rods and transferring rods. The holding and transferring rods are provided within the chamber, and extend between the inlet and the outlet of the chamber. The holding and transferring rods are rotatable so that they can rotate the protruding teeth into and out of engagement with the test trays. The teeth also act to support the trays in the upright position.

When the holding rods supporting the trays are rotated, the teeth formed on the holding rods are rotated downward so that they no longer block movement of the trays. The transferring rods, whose teeth are engaged with the trays, are then moved forward in the direction in which the trays are to move. As a result, the teeth formed on the transferring rods push the trays forward by one step. The holding rods are then reverse rotated so that they again support the trays, and the transferring rods are rotated so that the teeth in the transferring rods no longer engage the trays. Thus allows the transferring rods to be moved backwards in a direction opposite to the tray travel direction. When the transferring rods have been moved back, they are reverse rotated so that the teeth on the transferring rods again engage the trays. At this point, the cycle can be repeated to move the trays forward by another step.

When the tray finally reaches the end of the chamber, the tray is released from the teeth formed on the holding rod and the transferring rod pushes the tray, onto guide rails provided to an inside wall of the chamber.

The conventional tray-transferring apparatus is equipped with two or more holding and transferring rods at high and low positions within the chamber. Driving units have to be provided to drive the two or more holding and transferring rods. This makes a configuration of the tray-transferring apparatus complicated.

Furthermore, the holding and transferring rods must be rotated in directions opposite to each other, and the transferring rods must also be moved backwards and forwards in a straight line. The rotary and linear motion of the holding and transferring rods makes the configuration of the tray-transferring apparatus complicated.

### BRIEF DESCRIPTION OF THE DRAWINGS

The embodiments will be described in detail with reference to the following drawings in which like reference numerals refer to like elements, and wherein:

FIG. 1 is a cross-sectional view illustrating a tray-transferring apparatus;

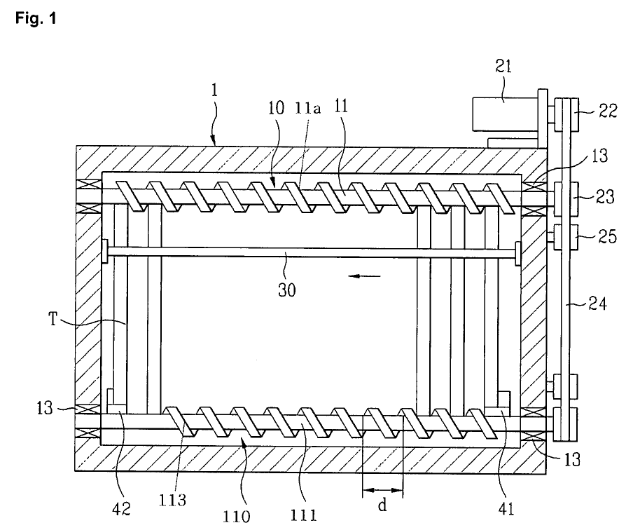

FIG. 2 is a perspective view illustrating the main components of the tray-transferring apparatus of FIG. 1; and

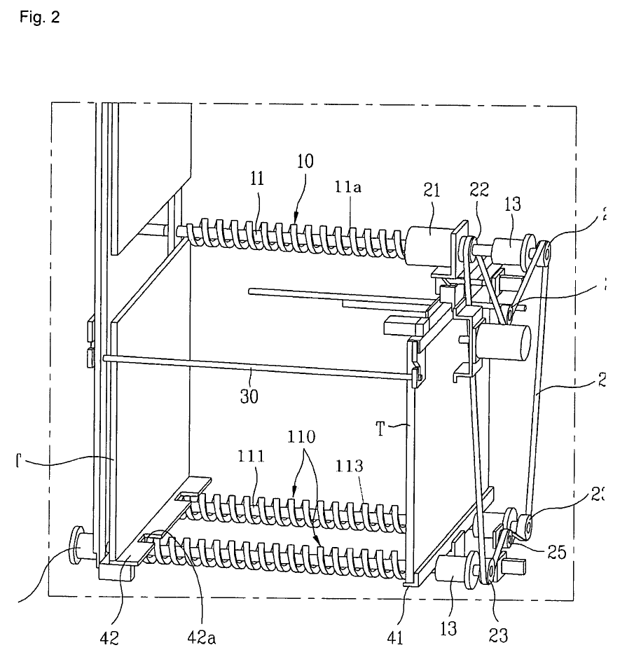

FIG. 3 is another perspective view illustrating main components of the tray-transferring apparatus of FIG. 1 from a different angle.

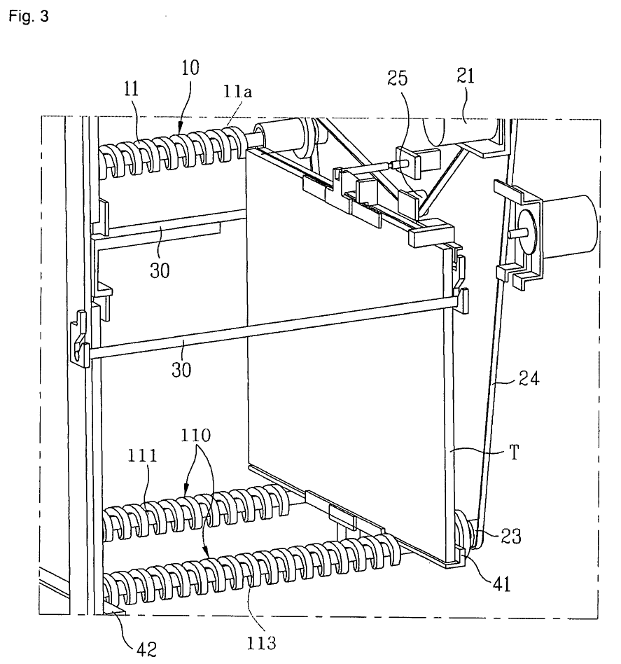

### DETAILED DESCRIPTION

In this embodiment, three transferring bars are used. However, in alternate embodiments, other numbers of transferring bars could be provided.

In the disclosed handler, transferring bars 10 are provided to extend from the internal front side of the chamber 1 to the internal rear side of the chamber 1. Each transferring bar has a screw thread 11a on its external surface. Edges of trays ‘T’ are inserted into the screw groove 11 of the threads 11a. In the illustrated embodiment, the chamber has two transferring bars supporting a lower side of the trays ‘T’ and one transferring bar supporting a upper side of the trays ‘T’. Ends of the transferring bars are rotatably supported by two bushings 13, which are provided at two lateral sides of the chamber 1, respectively.

A driving unit, which synchronously rotates the transferring bars 10, is provided on an external side of the chamber 1. The driving unit includes a motor 21, a drive pulley 22 connected to a shaft of the motor 21, and driven pulleys 23 connected to ends of each of the transferring bars 10. A belt 24 connects the drive pulley 22 and the driven pulleys 23. The belt 24 transmits rotary motion of the drive pulley 22 to the driven pulleys 23.

The motor 21 can be rotated in both directions, clockwise and counterclockwise. The motor 21 includes a servo motor giving positional control. An idler pulley 25 keeps the belt 24 at the correct tension.

A pair of guiding bars 30, guide and support lateral sides of the trays ‘T’ in such a manner that the tray ‘T’ moves forwards and backwards in a straight line. Guiding bars 30 are provided on both lateral sides of the chamber 1, respectively. The guiding bars 30 are provided in parallel with the transferring bars.

A front stand 41, on which a tray ‘T’ entering the chamber 1 is placed, is provided on the front side of the chamber 1. A rear stand 42, on which a tray exiting the chamber 1, is located at a rear side of the chamber 1. The front and rear stands 41 and 42 support the bottom side of the trays ‘T’. The front and rear stands have an ‘L’ shape. Two slots 42a are formed on the rear stand 42 in such a manner that the slots 42a are vertically aligned with the two transferring bars which are positioned under the rear stand 42.

A pushing unit is provided outside of the front side of the chamber 1 (on the right-hand side of the chamber 1 in FIGs). The pushing unit pushes a tray ‘T’ forward to move the tray ‘T’ over the transferring bars 10 when the tray ‘T’ enters the chamber 1 and is placed on the front stand 41. For example, the pushing unit may include an air-pressure cylinder and a pushing bar which is connected to a piston rod of the air-pressure cylinder to push the tray ‘T’ onto the transferring bars.

Operation of the tray-transferring apparatus according to the embodiment of the present invention is now described.

When temperature cycle testing is performed, the temperature inside the chamber is elevated or lowered by a temperature-adjusting device (not shown), which typically includes a heater and a liquefied gas injecting system for cooling. A tray ‘T’ containing packaged chips is introduced inside the chamber 1 and is placed on the front stand 41. At this point, the pushing unit pushes forwards the tray ‘T’ by a given distance to place the tray ‘T’ on the foremost parts of the transferring bars.

When a control signal is applied to the motor 21, the motor 21 operates to rotate the drive pulley 22. When the drive pulley 22 is rotated, the driven pulleys 23 and the transferring bars 10 are rotated by the rotary motion of the motor 21 transmitted by the belt 24. When the transferring bars rotate, the bottom side and upper side of the tray ‘T’, are inserted into the screw grooves of the transferring bars. Thus, the tray ‘T’ is moved forward along the grooves in a straight line.

A distance ‘d’ which the tray ‘T’ travels depends upon an amount of rotation of the transferring bar 10. During transfer of the tray ‘T’, the tray ‘T’ is guided and supported by both of the guiding bars 30 provided at sides of the chamber 1. Therefore, the trays are prevented from moving sideways out of the path of travel.

When the tray ‘T’ reaches the end of the transferring bars 10, the tray ‘T’ is placed on the rear stand 42. Thereafter it is transferred outside the chamber 1 by another tray-transferring apparatus.

In this way, the tray-transferring apparatus can transfer two or more trays ‘T’ by a given distance ‘d’ by rotating the transferring bars 10. The transferring bars may be rotated in forward and reverse directions. For example, when there is a great distance between a tray ‘T’ already in transit on the transferring bars 10 and a tray ‘T’ ready for transit, the tray ‘T’ in transit on the transferring bars 10 is moved backward by rotating the transferring bars in the reverse direction to adjust the distance between the preceding and following trays ‘T’. Thus, after the distance between the preceding tray ‘T’ and the following tray ‘T’ is adjusted, the preceding and following trays ‘T’ may be moved forwards by one step.

A tray ‘T’ can be moved to a given position by rotating the transferring bars because the distance which the tray ‘T’ travels depends upon the amount of rotation of the transferring bars 10.

In the above-described embodiment, which has the transferring bars 10 with the screw threads 11a and grooves 11 on their external surfaces, it is possible to transfer a tray ‘T’ in a smooth, speedy manner. This can be done with a minimum number of transferring bars 10.

A tray ‘T’ available for use in an conventional tray-transferring apparatus, if additionally equipped with a protrusion which can be inserted into the screw grooves 11 of the transferring bars 10, can be transferred by the tray-transferring apparatus according to the embodiment described above.

The tray-transferring apparatus described above does not apply vibration to the tray during transit. Thus, it is possible to minimize the likelihood that chips contained in the tray are ejected from the tray due to vibration generated during transfer of the tray.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although a number of embodiments have been described, it should be understood that numerous other modifications and embodiments can be devised by those skilled in the art that will fall within the spirit and scope of the principles of this disclosure. More particularly, variations and modifications are possible in the component parts and/or arrangements which would fall within the scope of the disclosure, the drawings and the appended claims. In addition to variations and modifications in the component parts and/or arrangements, alternative uses will also be apparent to those skilled in the art.

What is claimed is:

1. A handler for testing semiconductor chips including a tray-transferring apparatus, comprising:
at least one transferring bar that is rotatably mounted on the handler such that the at least one transferring bar extends in a tray travel direction, wherein screw threads are formed on an exterior surface of the at least one transferring bar, and wherein an edge of a chip transfer tray can be engaged with the screw threads; and
a driving unit that operates to rotate the at least one transferring bar such that a tray having an edge engaged in the screw threads of the at least one transferring bar is moved in the tray travel direction by the rotation of the at least one transferring bar.

2. The handler of claim 1, wherein the at least one transferring bar comprises a plurality of transferring bars.

3. The handler of claim 2, wherein the transferring bars are mounted on the handler such that two opposite sides of a tray can be engaged with the transferring bars.

4. The handler of claim 2, wherein the transferring bars are mounted on the handler such that they can engage upper and lower edges of trays.

5. The handler of claim 4, further comprising guiding bars mounted on the handler such that the guiding bars can support side edges of trays.

6. The handler of claim 1, wherein the screw threads on the at least one transferring bar are designed to engage protrusions formed on side edges of trays.

7. The handler of claim 1, wherein the driving unit comprises:
a motor; and
a motion transmitting apparatus for transmitting a rotary motion of the motor to the at least one transferring bar.

8. The handler of claim 7, wherein the motion transmitting apparatus comprises:
a drive pulley connected to a rotating shaft of the motor;
a driven pulley connected to each at least one transferring bar; and
a motion transmitting member transmitting a rotary motion of the drive pulley to the driven pulleys.

9. The handler of claim 8, wherein the motion transmitting apparatus further comprises an idler pulley that puts tension on the motion transmitting member.

10. The handler of claim 7, wherein the motor rotates in forward and backward directions.

11. The handler of claim 1, wherein the at least one transferring bar is configured to engage and transfer trays while the trays are vertically upright.

12. The handler of claim 1, wherein the at least one transferring bar is located within an environmental chamber of the handler, and wherein the driving unit is mounted outside of the environmental chamber.

13. The handler of claim 1, wherein the at least one transferring bar is mounted within an environmental chamber of the handler, and further comprising:
a front stand positioned at an input side of the chamber, wherein a tray can be supported on the front stand when the tray is introduced into the chamber; and
a rear stand positioned at an outlet side of the chamber, wherein a tray can be supported on the rear stand after it has moved through the chamber and before it is removed from the chamber.

14. The handler of claim 13, wherein at least one aperture is formed in the rear stand, the at least one aperture in the rear stand allowing a screw thread of a transferring bar located under the rear stand to protrude upward through the rear stand.

15. A handler for testing semiconductor chips, comprising:
an environmental test chamber;
a plurality of transferring bars extending from an input side of the chamber to an output side of the chamber, wherein screw threads are formed on external surfaces of the transferring bars, and wherein edges of a chip transfer tray can be engaged with the screw threads such that rotation of the transferring bars will cause a tray to move between the input and output sides of the chamber;
guiding members that extend from the input side to the output side of the chamber at lateral sides of the chamber; and
a driving unit that rotates the transferring bars.

16. The handler of claim 15, wherein at least one top transferring bar is located at a top of the chamber, and wherein at least one bottom transferring bar is located at a bottom of the chamber such that a tray can be positioned between the top and bottom transferring bars with top and bottom edges of the tray engaged with the screw threads on the top and bottom transferring bars, respectively.

17. The handler of claim 16, wherein the guide bars are mounted on the handler such that they can support side edges of trays that are positioned between the top and bottom transferring bars.

18. The handler of claim 15, wherein the driving unit comprises:
a rotational driver;
a rotational movement transferring element that extends between the rotational driver and the plurality of transferring bars to convey rotational movement of the rotational driver to the transferring bars.

19. The handler of claim 15, wherein the driving unit comprises:
a motor mounted outside the environmental chamber;
a driving pulley mounted on a rotational shaft of the motor;
driven pulleys mounted on each of the transferring bars; and
a drive belt that extends between the driving and driven pulleys.

20. The handler of claim 19, further comprising an idler pulley that also engages the drive belt and that acts to put tension on the drive belt.
